(19) United States
(12) Patent Application Publication
(10) Pub. No.: US 2005/0194660 A1
(43) Pub. Date: Sep. 8, 2005

(54) IGBT module

(75) Inventors: Kouichi Mochizuki, Fukuoka (JP); Yoshifumi Tomomatsu, Fukuoka (JP)

Correspondence Address: MCDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/858,047

(22) Filed: Jun. 2, 2004

(30) Foreign Application Priority Data
Feb. 12, 2004 (JP) JP2004-034578

(51) Int. Cl. H01L 27/082

(52) U.S. Cl. 257/565

(57) ABSTRACT

An IGBT module is configured with a plurality of IGBT cells connected to each other. The IGBT chips are each configured a plurality of unit cells connected to each other. The unit cells each include one IGBT element. Gate voltage is applied to the gate of the IGBT element from a common gate terminal through a gate pad and a gate resistor. Emitter voltage is applied to the emitter of the IGBT element from a common emitter terminal through an emitter pad. Collector voltage is applied to the collector of the IGBT element from a common collector terminal. The gate pad, gate transistor and emitter pad are provided for each of the unit cells. Thus obtained is an IGBT module capable of suppressing gate voltage oscillation without significantly increasing switching loss.

### BACKGROUND OF THE INVENTION

1. Field of the Invention

The present invention relates to an IGBT (insulated gate bipolar transistor) module, and more particularly, to a technique for suppressing gate voltage oscillation in IGBT chips.

2. Description of the Background Art

Gate insulated semiconductor devices such as IGBTs and MOSFETs have been used as power converters. An IGBT is equipped with both the high-speed operating characteristic offered by a MOSFET and the low on-state voltage characteristic offered by a bipolar transistor, and therefore, it has been widely used as a power converter such as an inverter. Further, IGBT chips having a rated current (an average current a chip can pass therethrough) of approximately several hundreds amperes have been offered recently, which contribute to size reduction of power modules. Generally, the rated current of an IGBT chip is proportional to its chip area.

IGBTs have been dramatically improved in performance, and improvements have been made year by year. In improvements in performance for reducing power loss and the like, increase in current-carrying capability by miniaturizing MOSFET parts configured in an IGBT is very important. However, with such miniaturization being advanced further, a short-circuit current disadvantageously increases, and recently, such increase in a short-circuit current (that is, increase in transfer characteristic) has raised the problem of gate voltage oscillation.

Such gate voltage oscillation is caused by parasitic capacitance and transfer characteristic of an IGBT and external inductance, and a resonance point exists in any semiconductor device. To suppress gate voltage oscillation, it is important to adjust actual operating conditions not to cause resonance. For this purpose, a method of decreasing a saturation current value of a device itself is considered. In the case of decreasing a saturation current value, however, IGBTs are degraded in performance.

For adjusting actual operating conditions not to cause resonance without decreasing a saturation current, a method of increasing a resistance value of a gate resistor for adjusting the switching speed connected to the outside of an IGBT chip is considered. This method is based on the fact that resistance functions as damping against resonance. Examples of IGBTs and MOSFETs improved in performance by increasing a gate resistance value of a gate resistor are disclosed in Japanese Patent Application Laid-Open Nos. 2003-152183, 2001-15672 and 02-42764 (1990).

As described above, gate voltage oscillation can be suppressed by increasing a gate resistance value. However, increase in gate resistance value decreases the switching speed, which increases switching loss. Particularly, with increase in capacity of an IGBT module, there are increasing cases where a plurality of large IGBT chips are connected in parallel to each other. In such cases, a gate resistance value increases accordingly, which disadvantageously results in significant increase in switching loss.

### SUMMARY OF THE INVENTION

It is an object of the present invention to provide an IGBT module capable of suppressing gate voltage oscillation without significantly increasing switching loss.

According to the present invention, the IGBT module comprises a plurality of resistors each having a first end and a second end and a plurality of IGBT elements provided in one-to-one correspondence to the plurality of resistors. Each of the plurality of IGBT elements has a collector, an emitter and a gate connected to the first end of a corresponding one of the plurality of resistors. The plurality of resistors are connected in common to each other at the second end. The plurality of IGBT elements are connected in common to each other at the collector and at the emitter, respectively. The plurality of IGBT elements are divided into groups, each group containing two or more of the plurality of IGBT elements, and the groups are respectively incorporated into semiconductor chips different from each other.

Dividing the IGBT elements into groups can reduce a rated current of the semiconductor chips as well as unbalance between currents respectively flowing through the semiconductor chips. Further, this division does not require adding bonding wires, which thus does not increase inductance. Gate voltage oscillation can therefore be suppressed. Furthermore, since a resistor is provided for each of IGBT elements, the resistance value of resistors in one semiconductor chip can be reduced than in the case of providing a resistor for each group including two or more of the IGBT elements. This can prevent decrease in switching speed as well as preventing increase in switching loss. Therefore, current consumed during a switching operation can be reduced.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of an IGBT module according to a first preferred embodiment of the present invention;

FIGS. 2 and 3 are graphs showing effectiveness of the IGBT module according to the first preferred embodiment;

FIG. 4 is a circuit diagram of an IGBT module according to a second preferred embodiment of the present invention;

FIGS. 5A and 5B illustrate the configuration of the IGBT module according to the second preferred embodiment; and

FIG. 6 is a circuit diagram of an IGBT module according to a third preferred embodiment of the present invention.

### DESCRIPTION OF THE PREFERRED EMBODIMENTS

### First Preferred Embodiment

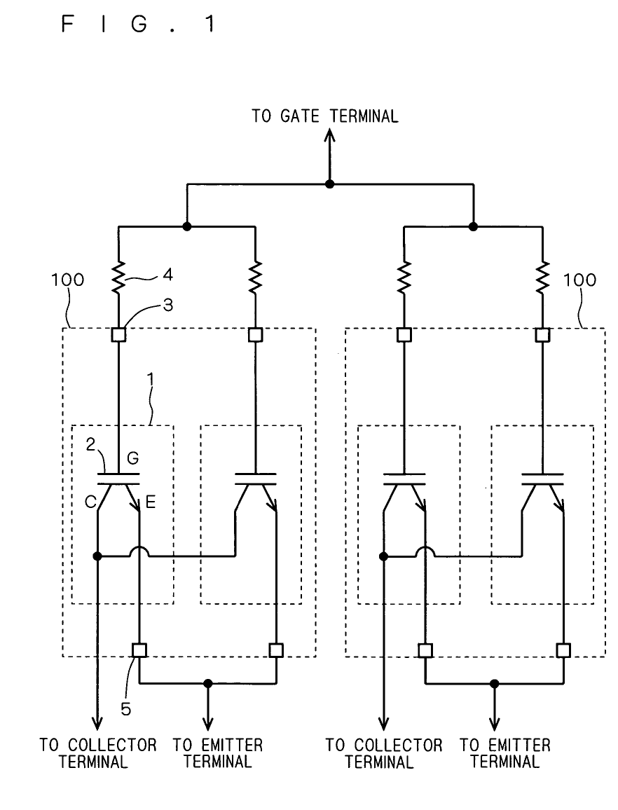

FIG. 1 is an equivalent circuit diagram of an IGBT module according to the present embodiment.

This IGBT module is configured with a plurality of IGBT chips (semiconductor chips) 100 (two IGBT chips 100 in FIG. 1) connected to each other. The IGBT chips 100 are each configured with a plurality of unit cells 1 (two unit cells 1 in FIG. 1) connected to each other.

The unit cells 1 each include one IGBT element 2. Gate voltage is applied to the gate G of the IGBT element 2 from a common gate terminal through a gate pad 3 and a gate resistor 4. Here, the gate G and gate pad 3 are connected to each other by an interconnect layer (not shown) within the IGBT chip 100. The gate pad 3 and gate resistor 4 are connected to each other by a bonding wire (not shown) provided outside the IGBT chip 100. That is, in FIG. 1, the resistor 4 has its first end connected to the gate pad 3 and its second end connected to the gate terminal.

Emitter voltage is applied to the emitter E of the IGBT element 2 from a common emitter terminal through an emitter pad 5. Collector voltage is applied to the collector C of the IGBT element 2 from a common collector terminal. The gate pad 3, gate transistor 4 and emitter pad 5 are provided for each of the unit cells 1.

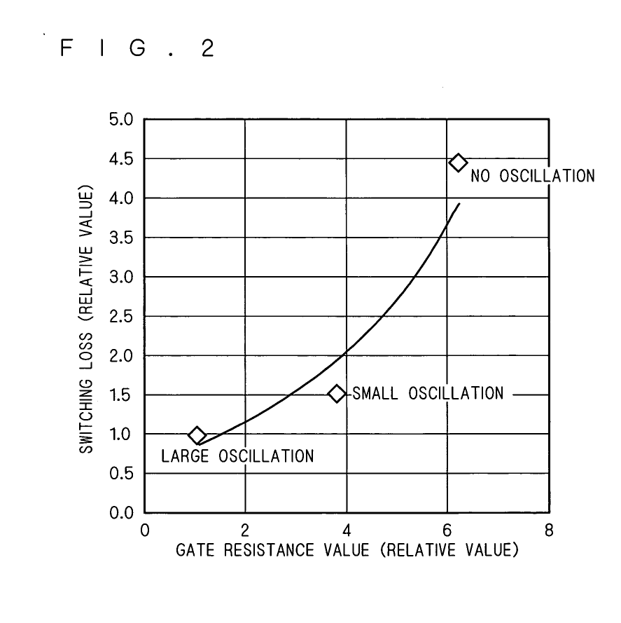

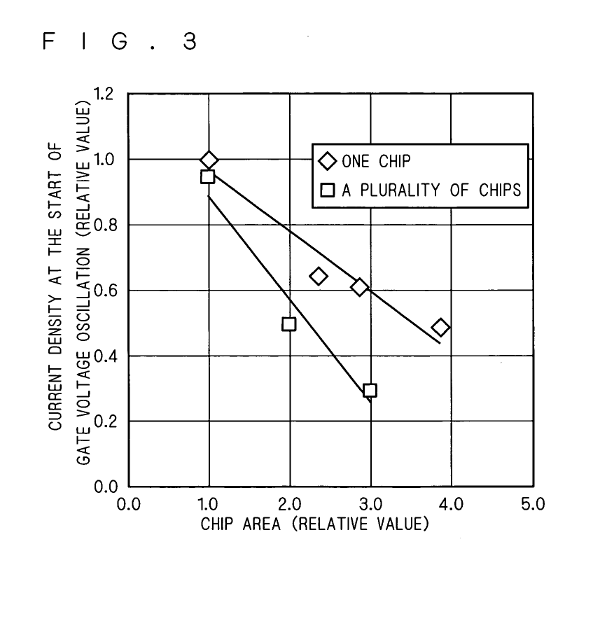

Next, operating characteristics of a general IGBT module will be described in reference to FIGS. 2 and 3. The curve in FIG. 2 and lines in FIG. 3 indicate expressions derived from measured values.

In FIG. 2, the horizontal axis represents gate resistance value (relative value), and the vertical axis represents switching loss (relative value) at the time of turn-on. As indicated by the measured values marked with the character ⋄, increase in gate resistance value decreases switching speed, thus increasing switching loss. However, FIG. 2 also shows that oscillation is less likely to occur under actual operating conditions with increases in gate resistance value. In other words, increase in gate resistance value is effective in suppressing oscillation, however, switching loss disadvantageously increases in such case.

In FIG. 3, the horizontal axis represents the chip area (relative value), and the vertical axis represents the current density (relative value) at the start of gate voltage oscillation. The mark ⋄ indicates a measured value in the case of using a single IGBT chip, and the mark □ indicates a measured value in the case of using a plurality of relatively small IGBT chips connected in parallel. In the case of using a plurality of IGBT chips, the total area of respective chips is plotted along the horizontal axis. The measured values marked with ⋄ and □ were all obtained without connecting a gate resistor to the IGBT chip or chips. The following two results are clear from the graph shown in FIG. 3.

A the first result, the measured values marked with ⋄ and □ show that the current density at the start of gate voltage oscillation decreases with increase in chip area. In other words, gate voltage oscillation is more likely to occur with increase in chip area. This is because unbalance between currents respectively flowing through unit cells configured in a chip results in gate voltage oscillation.

As the second result, comparison between the measured values marked with ⋄ and □ shows that gate voltage oscillation is more likely to occur in the case of using a plurality of chips connected to each other. This results from inductance caused by a bonding wire connecting gate terminals or emitter terminals of respective chips to each other.

On the other hand, in the IGBT module shown in FIG. 1, unit cells 1 adjacent to each other in the IGBT chip 100 are separated from each other at the gate pad 3, gate resistor 4 and emitter pad 5, respectively, so that the unit cells 1 in one IGBT chip 100 are divided from each other. By this division, the rated current can be reduced in one IGBT chip 100 (that is, chip area is reduced), which can reduce unbalance as shown by the first result. Further, this division does not require adding bonding wires, which thus does not increase inductance as shown by the second result. Gate voltage oscillation can therefore be suppressed.

Furthermore, the gate resistor 4 is provided for each of the unit cells 1 in the IGBT chip 100, the resistance value resulting from the gate resistor 4 provided outside the one IGBT chip 100 can be reduced more than in the case of providing the gate resistor 4 in common for a plurality of unit cells 1. This can prevent decrease in switching speed and increase in switching loss. Therefore, current consumed during a switching operation can be reduced.

### Second Preferred Embodiment

In the IGBT module according to the first preferred embodiment, the gate resistor 4 is provided on the outer side with respect to the gate pad 3 (that is, outside the IGBT chip 100), however, the gate resistor 4 may be provided on the inner side with respect to the gate pad 3 (that is, within the IGBT chip 100).

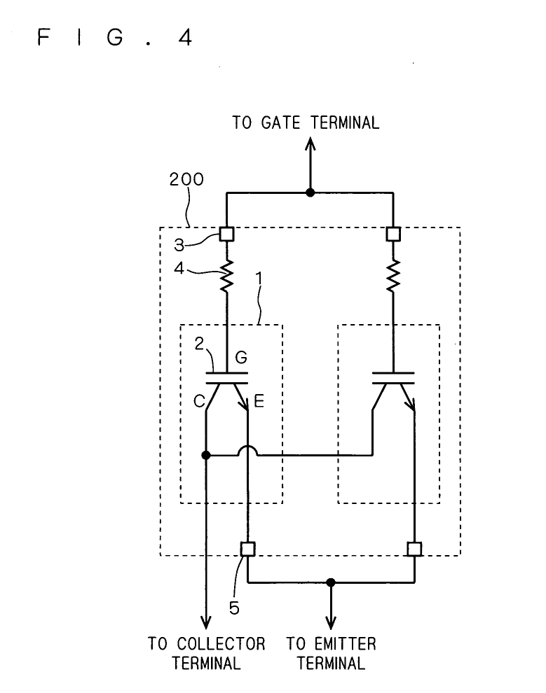

FIG. 4 is an equivalent circuit diagram showing the configuration of an IGBT module according to a second preferred embodiment of the present invention. An IGBT chip 200 shown in FIG. 4 is configured by shifting the gate resistor 4 in the IGBT chip 100 shown in FIG. 1 from the outer side to the inner side with respect to the gate pad 3. For ease of illustration, FIG. 4 only shows one of a plurality of IGBT chips 200.

In FIG. 1, the gate resistor 4 is connected to the outer side with respect to the gate pad 3 by a bonding wire.

On the other hand, in FIG. 4, the gate resistor 4 is provided on the inner side with respect to the gate pad 3 (i.e., within the IGBT chip 200), and is connected to the gate G of the IGBT element 2 by a gate interconnect line formed by interconnect layers in the IGBT chip 200 rather than by a bonding wire, as will be described below.

Specifically, in FIG. 4, the gate resistor 4 has its first end connected to the gate G of the IGBT element 2 and its second end connected to the gate pad 3.

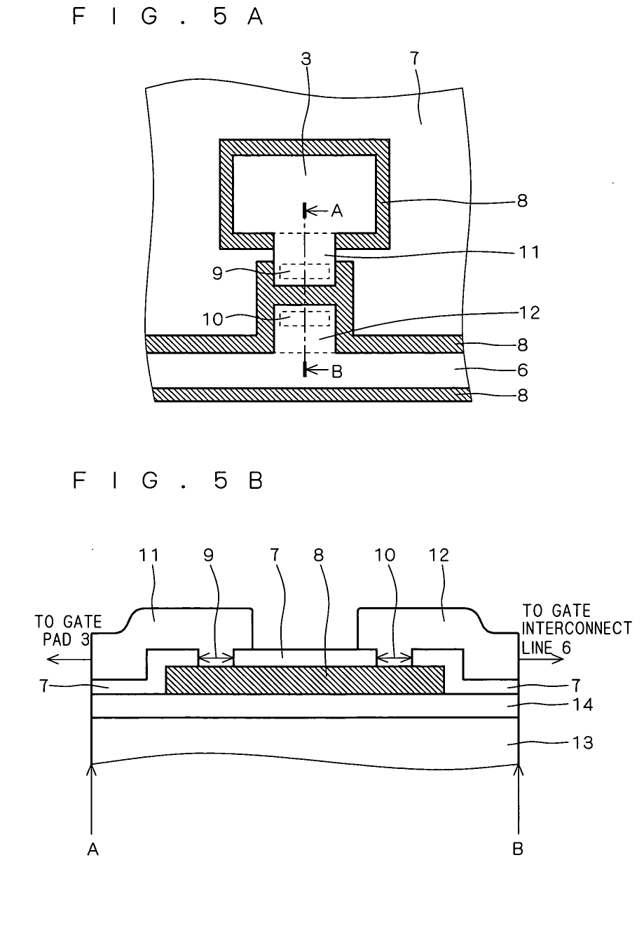

FIG. 5A is a top view of part of the IGBT chip 200 in the IGBT module according to the present embodiment, and FIG. 5B is a sectional view taken along the line A-B in FIG. 5A.

As shown in FIG. 5A, the gate pad 3 and a gate interconnect line 6 are surrounded by a polysilicon region 8. The gate pad 3 and gate interconnect line 6 are made of aluminum-silicon which is polysilicon containing aluminum.

As shown in FIG. 5B, an insulation film 14, the polysilicon region 8, and an interlayer insulation film 7 are formed in this order on a substrate 13 made of silicon. An aluminum-silicon region 11 extending from the gate pad 3 and an aluminum-silicon region 12 extending from the gate interconnect line 6 are formed on the interlayer insulation film 7. The aluminum-silicon regions 11 and 12 are respectively connected to the polysilicon region 8 by contact regions 9 and 10 which are openings provided on the interlayer insulation film 7. The gate pad 3 and gate interconnect line 6 are thereby electrically conducted. For ease of illustration, the interlayer insulation film 7 shown in FIG. 5B is partly omitted in FIG. 5A.

The polysilicon region 8 shown in FIG. 5B may be used as the gate resistor 4 shown in FIG. 4. Many of general IGBT chips have polysilicon regions. The use of such polysilicon regions as resistors can eliminate the step of forming the gate resistor 4 individually. It also eliminates the need to provide components such as resistor chips and wires. Further, space for providing these components can be reduced.

As described, the IGBT module according to the present embodiment can reduce the number of steps, the number of components and space, which can therefore achieve the effect of reducing manufacturing costs while improving productivity, in addition to the effects achieved by the first preferred embodiments.

Further, a bonding wire connected to the gate pad 3 is provided not on the inner side but on the outer side with respect to the gate resistor 4, which results in lower inductance than in the first preferred embodiment. Therefore, gate voltage oscillation can further be suppressed.

The above-mentioned polysilicon region 10 may be generated by filling a trench formed in the IGBT chip 200. Forming a trench in appropriate dimensions can reduce variations in resistance value, which can improve balance in parallel connection.

### Third Preferred Embodiment

In both the IGBT modules according to the first and second preferred embodiments, one gate pad 3 is provided for each gate resistor 4. In the IGBT module according to the second preferred embodiment, however, the gate resistor 4 is provided within the IGBT chip 200, and therefore, one gate pad 3 may be provided for each IGBT chip 200.

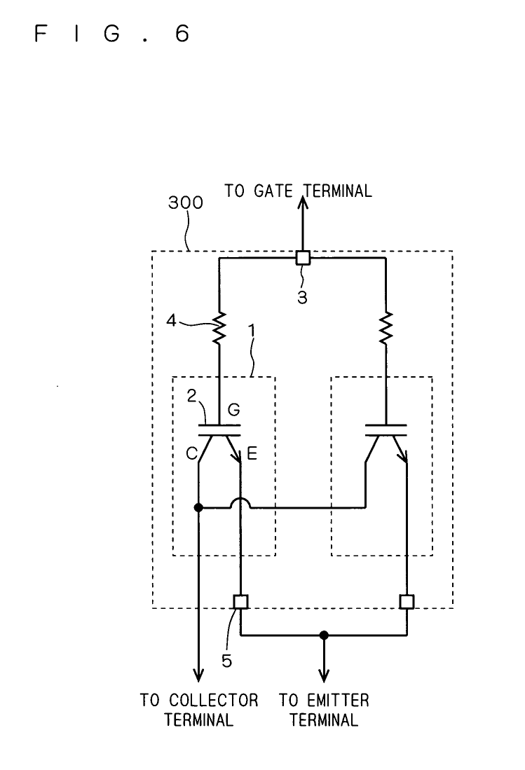

FIG. 6 is an equivalent circuit diagram showing the configuration of an IGBT module according to a third preferred embodiment. An IGBT chip 300 shown in FIG. 6 is configured by replacing the gate pads 3 in the IGBT chip 200 shown in FIG. 4 by a single gate pad 3. Specifically, in FIG. 6, the plurality of gate resistors 4 have their first ends connected to the gate G of a corresponding one of the IGBT elements 2 and their second ends connected to the gate pad 3 in common.

Therefore, the number of gate pads 3 can be reduced, which thus can reduce the IGBT chip 300 in area and can reduce the number of bonding wires connected to the gate pad 3.

As described, the IGBT module according to the present embodiment can achieve the effect of reducing manufacturing costs, in addition to the effects achieved by the second preferred embodiment.

In the IGBT module according to the present embodiment, a polysilicon region on the IGBT chip 300 may be used as a gate resistor as in the second preferred embodiment.

Further, the gate resistor 4 may have a negative temperature characteristic which increases the resistance value as temperature falls. According to a temperature characteristic of mobility of channel regions, a general IGBT element has a greater saturation current as temperature falls, so that gate voltage oscillation is more likely to occur. Therefore, the use of gate resistor 4 having a negative temperature characteristic can suppress gate voltage oscillation more effectively.

While the invention has been shown and described in detail, the foregoing description is in all aspects illustrative and not restrictive. It is therefore understood that numerous modifications and variations can be devised without departing from the scope of the invention.

1. An IGBT module comprising
a plurality of resistors each having a first end and a second end; and
a plurality of IGBT elements provided in one-to-one correspondence to said plurality of resistors, wherein
each of said plurality of IGBT elements has a collector, an emitter and a gate connected to said first end of a corresponding one of said plurality of resistors,
said plurality of resistors are connected in common to each other at said second end,
said plurality of IGBT elements are connected in common to each other at said collector and at said emitter, respectively, and
said plurality of IGBT elements are divided into groups, each group containing two or more of said plurality of IGBT elements, and said groups are respectively incorporated into semiconductor chips different from each other.

2. The IGBT module according to claim 1, wherein
said plurality of resistors are provided on the outside of said semiconductor chips, and
said semiconductor chips each include a plurality of pads through each of which each of said plurality of resistors and each of said plurality of IGBT elements are connected to each other.

3. The IGBT module according to claim 1, wherein
each of said plurality of resistors is incorporated into one of said semiconductor chips including one of said groups containing one of said plurality of IGBT elements corresponding to said each of said plurality of resistors, and
each of said semiconductor chips includes a pad connected to said second end of one of said plurality of resistors included in said each of said semiconductor chips.

4. The IGBT module according to claim 3, wherein
said pad includes a plurality of pads provided for each of said semiconductor chips in one-to-one correspondence to said plurality of resistors.

5. The IGBT module according to claim 3, wherein
said pad is connected in common to ones of said plurality of resistors at said second end in one of said semiconductor chips including said pad and said ones of said plurality of resistors.

6. The IGBT module according to claim 3, wherein
said plurality of resistors are each configured using a filling material for a trench formed in each of said semiconductor chips.

7. The IGBT module according to claim 4, wherein
said plurality of resistors are each configured using a filling material for a trench formed in each of said semiconductor chips.

8. The IGBT module according to claim 5, wherein
said plurality of resistors are each configured using a filling material for a trench formed in each of said semiconductor chips.
